(19) United States
(12) Patent Application Publication
(10) Pub. No.: US 2008/0035477 A1
(43) Pub. Date: Feb. 14, 2008

(54) Vacuum Coating System for Coating Elongate Substrates

(76) Inventors: Olaf Gawer, Dresden (DE); Jens Melcher, Dresden (DE); Steffen Lessmann, Dresden (DE); Erwin Zschieschang, Dresden (DE)

Correspondence Address: HESLIN ROTHENBERG FARLEY & MESITI PC, 5 COLUMBIA CIRCLE, ALBANY, NY, 12203, US

(21) Appl. No.: 10/577,600

(22) PCT Filed: Nov. 4, 2004
(86) PCT No.: PCT/DE04/02465

§ 371 Date: Feb. 5, 2007

(30) Foreign Application Priority Data
Nov. 4, 2003 (DE) 103 52 144.5

(51) Int. Cl. C23C 14/56; C23C 14/35; H01J 37/34

(52) U.S. Cl. 204/298.26; 204/298.23

(57) ABSTRACT

A vacuum coating system for coating elongate substrates includes one or several coating sections and one or several pump sections, at lease one magnetron in an arrangement as a sputter-down-variant above the substrate which has a target surface opposite the upper side of the substrate and/or in an arrangement as a sputter-up-variant below the substrate which has a target surface opposite the lower side of the substrate, and a transport device. The aim is to form an inline coating system for the two lateral coatings of elongate substrates, wherein construction costs and space required are reduced. The aim is achieved by use of a transport device arranged in a divided manner on a drive plane and on a transport plane. In sputter-up-variants, the underside of a magnetron body containing the magnetron lies above the drive plane.

The invention relates to a vacuum coating system for coating elongate substrates, said coating system having one or several coating sections and one or several pump sections, at least one magnetron in an arrangement as a sputter-down-variant above the substrate, said variant having a target surface opposite the upper side of the substrate and/or comprising an arrangement as a sputter-up-variant below the substrate, said variant having a target surface opposite the lower side of the substrate and a transport device.

This twin-sided coating principle has industrial applications, for example, inline multi-chamber glass-coating systems. Flat and elongate glass sheets to be coated are transported horizontally through the successively arranged coating and pump sections by the transport system and are coated from above and/or below as required. For this purpose, the magnetrons are installed in the arrangement described above with respect to the substrate, either in one and the same coating section or also in separate coating sections. The transport system containing the drive elements and the transport elements for the substrate to be transported lies along a plane that is roughly equidistant to the magnetrons of the sputter-down and sputter-up mode, thus structurally dividing these two coating areas into an upper and a lower side. Separate mounting strictures and openings are therefore provided on the upper and lower side of the sections of the vacuum coating chamber to facilitate the assembly and disassembly of the magnetrons and pumps for the sputter-down and sputter-up modes.

The basic design of this type of coating system is known from the publication EP 1 179 516 A1, which describes an arrangement and method for coating both sides of glass substrates that are passed through the coating system in a constant position.

A significant drawback of coating systems of the be described above is that the separate arrangement of the magnetrons and pumps on the upper and lower sides of the coating section requires the provision of corresponding assembly and maintenance clearance either below or beside the coating system, which is associated with substantial construction costs. If the magnetrons and pumps are mounted from below, this requires that the entire length of the coating system is elevated. Lateral mounting of the magnetrons and pumps involves the integration at great expense of special pull-out trolleys into the coating system.

Furthermore, to prevent obstruction to the coating process, transport elements and drive components must not be arranged in the vicinity of the sputtering sources in the sputter-up mode, with the result that the greater spans of the transport elements and drive components used in this area require a coating section that is longer and wider overall than is the case in the single-sided coating of substrates.

Therefore, the aim of the invention is to form an inline coating system for coating both sides of elongate substrates, wherein construction costs and space required are reduced.

The aim of the invention is achieved by virtue of the fact that the transport device is arranged in a divided manner on a drive plane and on a sport plane. The drive plane is arranged in such a manner that in the sputter-up variant, the underside of a magnetron body containing the magnetron lies above the drive plane.

In this arrangement of the transport device, the drive components no longer lie between the magnetrons for the sputter-up mode and the substrate. Power is transmitted from the drive plane to the transport plane for the transport elements, such as the transport rollers, at right angles to the drive plane and this is possible at any point in the coating and pump sections.

On the one hand, this arrangement allows magnetrons to be fitted from above for both the sputter-up and sputter-down modes, which simplifies handling during assembly and maintenance and also avoids the need to elevate the system on upright supports. On the other hand, the drive components remain undisturbed and outside the sputter chamber, which results in greater operational safety. There is now also sufficient clearance on the drive plane to accommodate the drive components and to allow the external dimensions of the transport device to be reduced so that the widths and lengths of the vacuum chambers can be shortened.

Furthermore, the arrangement of the transport device offers the great advantage of allowing for more flexible configuration of the positions of the powered transport rollers and their horizontal connecting elements for transmitting power. This permits greater spans and clearances between the powered transport rollers. As a result, the magnetrons and pumps for the sputter-up process can be installed from the top down, as the lower coating chamber is now accessible along the entire transport plane. The assembly path is now the same as that used for the magnetrons and pumps for the sputter-down process and additional assembly access points are no longer required. This results in significant savings in terns of construction costs and space requirements in the coating systems.

In an advantageous configuration of the vacuum coating system according to the invention, transport elements of the transport plane can be disconnected from the drive system and removed if required.

The drive power of the flat substrate is transmitted from the drive plane via short lines to the transport rollers in the transport plane. The tort path comprises a multiplicity of short lines comprising no more than three transport rollers connected to one another. The transport rollers that form the line end are easy to remove from the transport path without disturbing the power transmission path of the drive power to the flat substrate. This embodiment further simplifies the assembly work required for the magnetrons and pumps and increases the flexibility in the structure of the spans and clearances between the transport elements.

In a practical continuation of the vacuum coating system according to the invention, in an arrangement as a sputter-up variant, the magnetron is connected to fastening elements that laterally extend from the top of the vacuum coating system alongside the substrate as far as the magnetron body.

In this way, the magnetron for the sputter-up variant can be fitted from above into the lower coating area. Assembly costs for separate fastening in the lower coating area and corresponding assembly and maintenance clearance are no longer necessary.

A further execution provides for drive elements of the drive plane to be encased in such a way that the casing acts as flow resistance.

As the transport device now penetrates the coating and pump sections in two planes, namely the drive plane and the transport plane, it is favorable to configure the penetration of the transport device in the drive plane as flow resistance so that no additional pressure equalization occurs between the sections. Encasing of the drive elements acts as flow protection here.

In a favorable execution of the vacuum coating system according to the invention, mutually corresponding suction openings are arranged in the coating section and the pump section above and below the transport plane.

This enables suction into the pump section from the upper coating area of an adjacent coating section in sputter-down mode and/or from the lower coating area of an adjacent coating section in sputter-up mode as required, as well as from the adjacent coating section on the left and/or right. The adjustability of the suction openings by means of correspondingly arranged flow orifices results in flexible adaptation possibilities of the pump section with any adjoining arrangement of coating sections in sputter-down and sputter-up modes.

Supplementary to the arrangement of the suction openings, it is favorable for an additional vacuum pump to be arranged below the sport plane in the pump section.

In addition to the vacuum pump arranged on the cover of the pump section, a vacuum pump can also be laterally arranged in the lower coating area below the transport plane with the result that alternative vacuum suction can be selected at the top or bottom or a parallel suction operation of two vacuum pumps through a single pump section can occur. For example, adjacent coating sections can also be operated at different vacuum operating pressures through the use of two vacuum pumps in only one pump section and with corresponding flow orifices. This further increases application flexibility and the optimization of the space requirement of the pump section for the twin-sided coating system.

Furthermore, it is advantageous for the connection for power transmission from the drive plane to the transport plane to be arranged in the coating section only.

With this arrangement, no vertically arranged transport elements are provided in the pump section in the area below the transport plane. The pump section, which has very slight dimensions in its longitudinal extent, must not be extended when using an additional vacuum pump with lateral suction in the area below the transport plane. In contrast, the space for the connection from the drive plane to the transport plane is available in the coating section without having to extend the dimensions. The power transmission to the transport elements in the transport plane of the pump section is carried out via a line of transport rollers connected to one another, with the line end extending into the pump section. In this way, the previously used standard length dimensions for the coating and pump sections in twin-sided coating systems can be retained.

The invention is described in more detail below on the basis of an execution example. In the associated drawings,

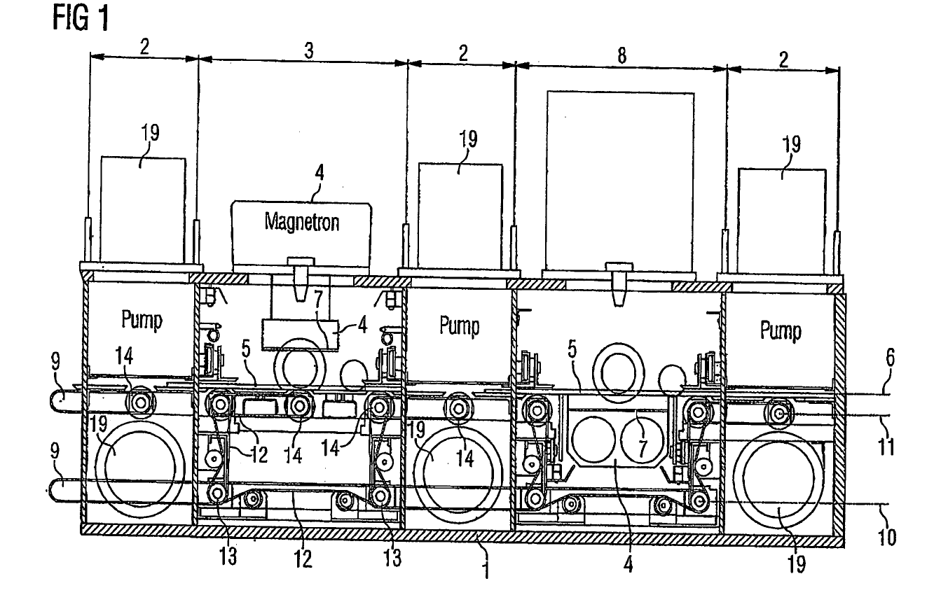

FIG. 1 shows a longitudinal section through an inline coating system with the twin-side coating principle and a transport device arranged in a divided manner in a transport plane and a drive plane, and

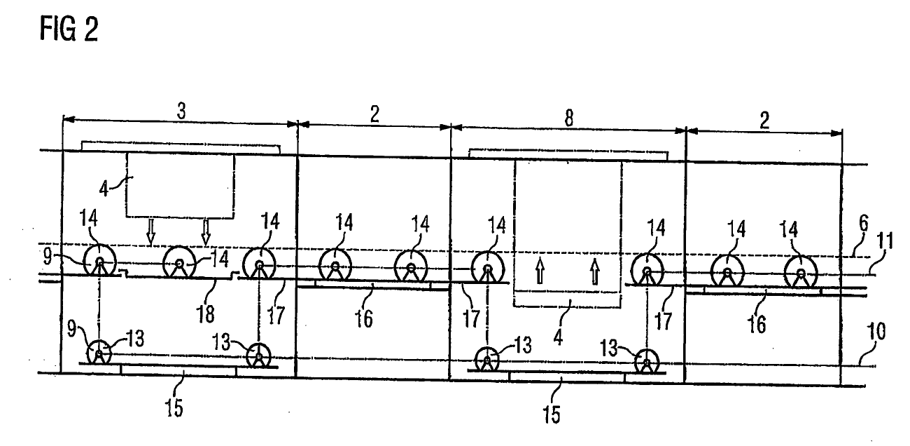

FIG. 2 shows a schematic representation of this inline coating system.

In the left-hand section of the vacuum coating system 1, a coating section in sputter-down mode 3 is shown between two pump sections 2; this means that a magnetron 4 for coating the substrate 5 from above is arranged above the substrate plane 6, the target surface 7 being opposite to the top side of the substrate 5. In the right-hand section of the vacuum coating system 1, a coating system in sputter-up mode 8 is arranged between two pump sections 2. Here, coating is carried out from above onto the substrate 5, in that a magnetron 4 is arranged below the substrate plane 6, the target surface 7 being opposite to the underside of the substrate 5.

The transport device 9 is situated in two planes, the drive plane 10 and the transport plane 11. The drive plane 10 accommodates the drive elements, such as the motor with the drive shaft (not shown), the toothed belt transmission 12 and the drive rollers 13, whereas only the toothed belt transmission 12 and powered or unpowered transport rollers 14 are arranged in the transport plane 11.

The function of this report device is particularly illustrate in the schematic representation in FIG. 2. The drive power is transmitted from the drive plane 10 to the transport plane 11 by means of a connection of the toothed belt transmission 12 guided perpendicular to the drive plane 10. There are two such connections in each of the coating sections 3 and 8, thus ensuring that every second and up to a limit of every third transport roller 14 is driven by a drive roller 13 of the drive plane 10. Consequently, the horizontal connections of the toothed belt transmission 12 for power transmission in the transport plane 11 are short lines and extend across no more than 3 transport rollers 14. The power transmission of the transport device 9 can be carried out through these branchings in sections in a parallel manner or alternatively in the drive plane 10 and the transport plane 11.

The substructure for mounting the drive elements 15 in the drive plane 10 is affixed to the base of the coating and pump sections 2, 3 and 8, whereas the transport rollers 14 are mounted on a substructure for the transport elements 16 in the transport plane 11. The substructure for the transport elements 16 consists of chamber elements 17 firmly attached to the sidewalls of the coating and pump sections 2, 3 and 8 and removable bridge elements 18. For inserting and positioning the magnetron 4 in the coating section of the sputter-up variant 8, a horizontal connection of the toothed belt transmission 12 in the transport plane 11 and a removable bridge element 18 with one or two transport rollers 14 is removed without impairing the transmission of the drive power to the substrate 5. A sufficiently large span of the transport rollers 14 for assembly of the magnetron 4 and the other process-specific fixtures in the sputter-up variant from above is attained via the same available opening as for maintenance and assembly of the magnetron 4 in the sputter-down variant. The fixtures for the sputter-up variant are fastened by means of a suspension structure (not shown), which skirts outside the substrate width on the substrate 5 below the transport pane 11. For a multivalent use of the pump sections 2, the vacuum pump 19 is arranged in the convention arrangement on the pump section 2 for upward suction or alternatively below the transport plane 11 for lateral suction.

Vacuum coating system for coating elongate substrates

### REFERENCE LIST

1 Vacuum coating system
2 Pump section
3 Coating section of the sputter-down variant
4 Magnetron
5 Substrate
6 Substrate plane
7 Target surface
8 Coating section of the sputter-up variant
9 Transport device
10 Drive plane
11 Transport plane
12 Toothed belt transmission
13 Drive roller
14 Transport roller
15 Substructure for the drive elements
16 Substructure for the transport elements
17 Fixed chamber elements
18 Removable bridge elements
19 Vacuum pump

1. Vacuum coating system for coating elongate substrates, said coating system having one or several coating sections and one or several pump sections, at least one magnetron in an arrangement as a sputter-down-variant above a substrate, said variant having a target surface opposite an upper side of the substrate and/or in an arrangement as a sputter-up-variant below the substrate, said sputter-up-variant having a target surface opposite a lower side of the substrate, and a transport device, wherein the transport device is arranged in a divided manner on a drive plane and on a transport plane, the drive plane being arranged in such a manner that in the sputter-up-variant, an underside of a magnetron body containing the magnetron lies above the drive plane.

2. Vacuum coating system according to claim 1, wherein transport elements of the transport plane can be disconnected from the drive system and removed without impairing transmission of drive power to the substrate.

3. Vacuum coating system according to claim 1, wherein, in an arrangement as a sputter-up-variant, the magnetron is connected to fastening elements that laterally extend from a top of the vacuum coating system alongside the substrate as far as the magnetron body.

4. Vacuum coating system according to claim 1, wherein drive elements of the drive plane are encased by a casing which acts as flow resistance.

5. Vacuum coating system according to claim 1, wherein mutually corresponding suction openings are arranged in a coating section and a pump section above and below the transport plane.

6. Vacuum coating system according to claim 1, wherein a vacuum pump is arranged below the transport plane in a pump section.

7. Vacuum coating system according to claim 1, wherein connection for power transmission from the drive plane to the transport plane is arranged in a coating section only.
